(19) United States
(12) Patent Application Publication
(10) Pub. No.: US 2023/0299114 A1
(43) Pub. Date: Sep. 21, 2023

(54) PHOTODETECTOR, PHOTODETECTOR ARRAY, AND DISTANCE MEASUREMENT SYSTEM

(71) Applicant: Panasonic Intellectual Property Management Co., Ltd., Osaka (JP)

(72) Inventors: Akito INOUE, Aichi (JP); Yutaka HIROSE, Kyoto (JP)

(21) Appl. No.: 18/325,709

(22) Filed: May 30, 2023

Related U.S. Application Data
(63) Continuation of application No. PCT/JP2021/041947, filed on Nov. 15, 2021.

(30) Foreign Application Priority Data
Dec. 10, 2020 (JP) 2020-205037

(51) Int. Cl. H01L 27/146; G01S 7/481

(52) U.S. Cl. CPC H01L 27/14645; H01L 27/14636; H01L 27/14616; G01S 7/4816

(57) ABSTRACT

A photodetector includes: a single-photon avalanche diode (SPAD); and a first resistor connected in series to the SPAD. In a recharge period in which an electric charge is discharged from the SPAD via the first resistor, an electric charge disappears from a multiplication region in the SPAD.

### CROSS REFERENCE TO RELATED APPLICATIONS

This is a continuation application of PCT International Application No. PCT/JP2021/041947 filed on Nov. 15, 2021, designating the United States of America, which is based on and claims priority of Japanese Patent Application No. 2020-205037 filed on Dec. 10, 2020. The entire disclosures of the above-identified applications, including the specifications, drawings and claims are incorporated herein by reference in their entirety.

### FIELD

The present disclosure relates to photodetectors, and particularly relates to photodetectors as exemplified by solid-state imaging devices, to photodetector arrays, and to distance measurement systems capable of detecting subtle light.

### BACKGROUND

In recent years, single-photon avalanche diodes (SPADs) are used in a broad range of fields such as health care, communications, biology, chemistry, monitoring, vehicle installation, radiation detection, etc. A SPAD is a photodiode with light detection sensitivity enhanced by multiplying, with the use of an avalanche breakdown phenomenon, a signal charge generated through photoelectric conversion (see Patent Literature (PTL) 1 and Non-Patent Literature (NPL) 1 through NPL 5).

### CITATION LIST

### Patent Literature

PTL 1: Japanese Unexamined Patent Application No. H7-176782

### SUMMARY

### Technical Problem

The present disclosure has an object to provide a photodetector, a photodetector array, and a distance measurement system that reduce a quenching dead time.

### Solution to Problem

In order to achieve the above object, a photodetector according to one aspect of the present disclosure includes: a single-photon avalanche diode (hereinafter referred to as a SPAD); and a first resistor connected in series to the SPAD. In a recharge period in which an electric charge is discharged from the SPAD via the first resistor, an electric charge disappears from a multiplication region in the SPAD.

An excess bias voltage applied to the SPAD is less than the breakdown voltage of the SPAD, and the resistance value R of the first resistor may satisfy expression (21) which will be described later.

A photodetector array according to one aspect of the present disclosure includes N photodetectors each of which is the photodetector described above, where N is an integer of 2 or greater. N series circuits included in the N photodetectors are connected in parallel. Each of the N series circuits includes the SPAD and the first resistor that are connected in series. N ends on a SPAD side are connected to each other, where the N ends are one ends of the N series circuits. The photodetector array further includes a second resistor that is connected to the N ends connected to each other and is connected in series to the N photodetectors. The resistance value of the second resistor is less than one N-th of the resistance value of the first resistor.

A distance measurement system according to one aspect of the present disclosure includes: a light receiver including the photodetector described above; a light emitter that emits light toward a measurement target; and a controller that controls the light receiver and the light emitter. The controller receives, from the light receiver, a signal corresponding to reflected light reflected by the measurement target, and calculates the distance to the measurement target.

### Advantageous Effects

According to the photodetector, photodetector array, and distance measurement system according to the present disclosure, a quenching dead time can be reduced.

### BRIEF DESCRIPTION OF DRAWINGS

These and other advantages and features will become apparent from the following description thereof taken in conjunction with the accompanying Drawings, by way of non-limiting examples of 10 embodiments disclosed herein.

FIG. 1A is a diagram illustrating a circuit example of a photodetector according to an embodiment.

FIG. 1B is a diagram illustrating a list of physical quantities used for a simulation illustrated in FIG. 1A.

FIG. 1C is a diagram illustrating a list of physical constants used for the simulation illustrated in FIG. 1A.

FIG. 2 is a diagram illustrating voltage fluctuation calculated from the simulation and changes over time in the number of electrons in a depletion layer.

FIG. 3 is a diagram illustrating changes over time in a reverse bias voltage when avalanche multiplication occurs.

FIG. 4 is a diagram illustrating a circuit example of a photodetector according to Embodiment 1.

FIG. 5 is a diagram illustrating a variation of the photodetector according to Embodiment 1.

FIG. 6 illustrates one example of a chart illustrating whether quenching can be performed or not with respect to an excess bias voltage and the resistance value of the first resistor.

FIG. 7 illustrates one example of a chart illustrating whether quenching can be performed or not with respect to the capacitance value of the first capacitor and the resistance value of the first resistor.

FIG. 8 is a block diagram illustrating a configuration example of a control system including a photodetector according to Embodiment 2.

FIG. 9 is a block diagram illustrating another configuration example of the control system including the photodetector according to Embodiment 2.

FIG. 10 is a circuit diagram of a photodetector that implements the control system illustrated in FIG. 8 or FIG. 9.

FIG. 11 is a diagram illustrating a circuit example of a photodetector array according to Embodiment 3.

FIG. 12 is a diagram illustrating a circuit example of a solid-state imaging device according to Embodiment 3.

FIG. 13 is a diagram illustrating a layout example of a plan view of the solid-state imaging device illustrated in FIG. 12.

FIG. 14 is a diagram illustrating a variation of the layout example of the plan view of the solid-state imaging device illustrated in FIG. 13.

FIG. 15 is a diagram illustrating an example of a cross-sectional configuration of the solid-state imaging device taken along the line XV-XV in FIG. 13.

FIG. 16 is a diagram illustrating a variation of the cross-sectional configuration of the solid-state imaging device taken along the line XV-XV in FIG. 13.

FIG. 17 is a diagram illustrating another example of a cross-sectional configuration of a solid-state imaging device according to Embodiment 3.

FIG. 18 is a schematic layout diagram illustrating a plan view of the whole of the solid-state imaging device illustrated in FIG. 17.

FIG. 19 is a block diagram illustrating one example of a distance measurement system using a photodetector or a photodetector array according to the present disclosure.

FIG. 20 is a diagram illustrating an example of a timing chart in the distance measurement system illustrated in FIG. 19.

### DESCRIPTION OF EMBODIMENTS

### Underlying Knowledge Forming Basis of the Present Disclosure

The inventors have found that the following problems regarding the single-photon avalanche diode (SPAD) described in the “Background” section arise.

NPL 1 presents a configuration in which circuit elements (quenching elements or quenching resistors), such as resistors and transistors referred to as quenching elements for their functions to instantly stop the multiplication of an electric charge caused by SPAD avalanche breakdown (i.e., perform quenching), are connected to the SPAD in series. Furthermore, NPL 1 shows simulation results, and recites that a resistance value is 300 kilohms on page 131. NPL 1, however, neither discloses the device structure of the SPAD nor specific expressions or relationships for circuit constants.

NPL 2 discloses a configuration that reduces a quenching dead time by controlling a reverse bias voltage at both ends of SPAD in accordance with output from the SPAD. As used herein, a quenching dead time is a time from the start of avalanche multiplication until a reverse bias voltage applied to the SPAD and fluctuated returns to a state that allows multiplication again.

NPT 2, however, does not disclose a configuration that controls a quenching resistor in the SPAD, and does not teach a relationship between (i) a resistance value required for the quenching resistor and (ii) the structure, property values, or bias conditions of the SPAD. Specifically, the bias conditions are an APD capacitance, a breakdown voltage (V_{BD}), a depletion layer width, and an excess bias voltage (excess voltage (Vₑₓ)).

PTL 1 presents a configuration that controls, in accordance with a current flowing through an APD, a reverse bias voltage applied to the APD, but does not teach control over, for instance, a quenching resistor and the capacitance of the APD.

As used herein, quenching is one of SPAD operational principles and means immediately stopping avalanche multiplication at a constant multiplication rate. A SPAD is an avalanche photodiode and is an element that is used with a breakdown voltage or higher and can multiply, through avalanche multiplication, electrons generated from a single photon and detect the electrons.

The inventors have discovered that a prerequisite required for a SPAD quenching resistor is that “carriers disappear from a depletion layer in a quenching recharge process” from dynamics simulations in quenching, and discovered conditions for resistors as in expression (21) which will be described later.

If based on the above discovery, it is possible to set the resistance value of a quenching resistor lower or proactively control the quenching resistor, and thus reduce a quenching recharge time, i.e., a quenching dead time to be less than the quenching dead time of a conventional SPAD. This can achieve sensitivity enhancement and dynamic range extension of a SPAD.

Hereinafter, embodiments of the present disclosure will be described in detail with reference to the drawings.

The embodiments described below each present a general or specific example. The numerical values, shapes, materials, elements, the arrangement and connection of the elements, steps, an order of the steps, etc., described in the following embodiments are mere examples, and therefore are not intended to limit the present disclosure.

### Simulation Forming the Basis of the Present Disclosure

First, a simulation forming the basis of the present disclosure will be described.

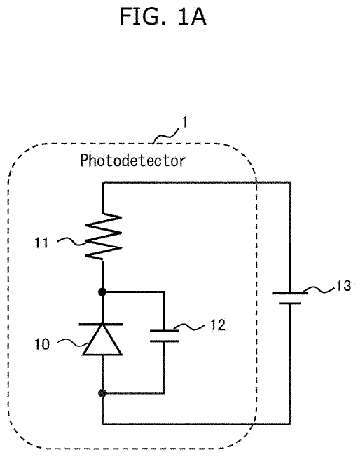

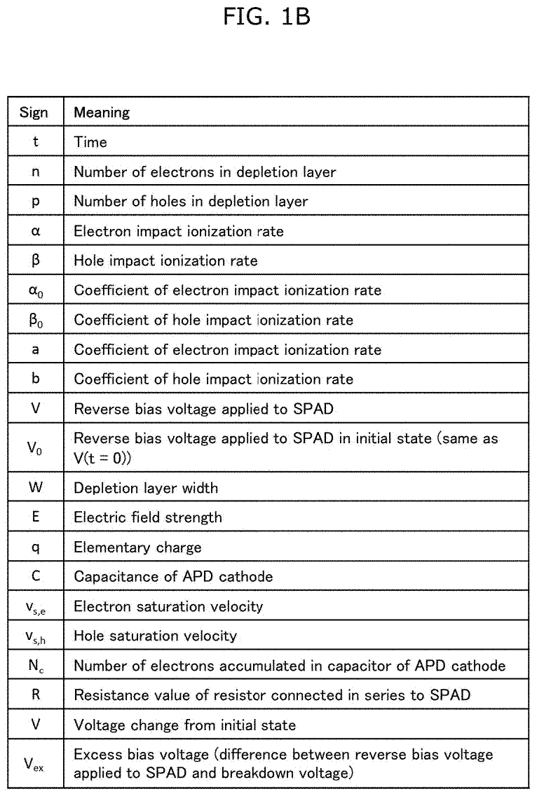

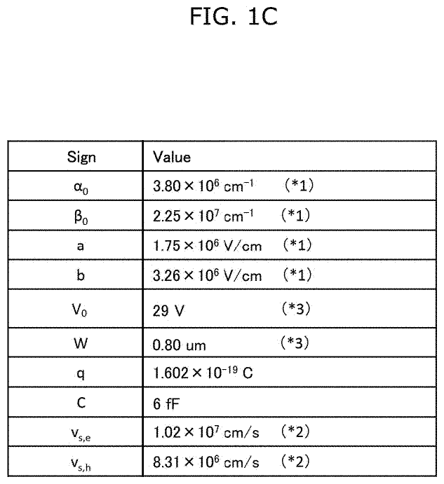

FIG. 1A is a diagram illustrating a circuit example of photodetector 1 according to an embodiment. FIG. 1A illustrates also power supply 13 besides photodetector 1. This circuit example is a circuit diagram according to the simulation forming the basis of the present disclosure.

Photodetector 1 includes SPAD 10, first resistor 11 connected in series to the anode of SPAD 10, and first capacitor 12 connected in parallel to SPAD 10. In FIG. 1A, first resistor 11 is connected to SPAD 10 on the cathode side, but may be connected to SPAD 10 on the anode side. A reverse bias voltage of at least a breakdown voltage is applied to SPAD 10 at least in an idling state in which no electric charge is present in a depletion layer. First capacitor 12 has the capacitance of the cathode of SPAD 10 and has a capacitance including the parasitic capacitance of SPAD 10. In other words, first capacitor 12, having a capacitance including parasitic components such as conjunction capacitance and wire capacitance of SPAD 10, does not need to have an external capacitance, and the type of first capacitor 12 is non-limiting. Stated differently, when having no external capacitance, first capacitor 12 has the parasitic capacitance of SPAD 10, and when having an external capacitance, first capacitor 12 has a sum of the parasitic capacitance of SPAD 10 and a capacitance component parallel to SPAD 10.

In the simulation using the circuit illustrated in FIG. 1A, changes over time in carriers inside SPAD 10 are simulated. FIG. 1B illustrates physical quantities used in the simulation. FIG. 1C illustrates physical constants used in the simulation. Physical constants with the sign (*1) in FIG. 1C are referenced from NPL 3. Physical constants with the signs (*1) and (*2) may take different values depending on, for instance, materials and temperature.

Physical constants with the sign (*3) are parameters that are set discretionarily and are determined by, for instance, an externally applied voltage, a device structure, and impurity concentration. This simulation and the physical constants in FIG. 1C assume the case of using silicon, but material is non-limiting and may be changed to other material. In this case, the physical constants in FIG. 1C may be changed according to the material. Examples of the other material include germanium, gallium arsenide, gallium nitride, indium phosphide, selenium, etc.

Changes over time in the number of electrons and the number of holes in the depletion layer in SPAD 10 when avalanche multiplication is caused by a single photon are expressed by differential equations (1) and (2) below.

$$[ Math . 1 ]$$

$$\frac{dn ( t )}{dt} = α ( E ( t ) ) {v}_{s , e} n ( t ) + β ( E ( t ) ) {v}_{s , h} p ( t ) - \frac{2 {v}_{s , e}}{W} n ( t ) \qquad ( 1 )$$

$$\frac{dp ( t )}{dt} = α ( E ( t ) ) {v}_{s , e} n ( t ) + β ( E ( t ) ) {v}_{s , h} p ( t ) - \frac{2 {v}_{s , e}}{W} p ( t ) \qquad ( 2 )$$

Here, the following relational expressions hold true for impact ionization rates.

$$[ Math . 2 ]$$

$$α ( E ( t ) ) = {α}_{0} \cdot exp ( - \frac{a}{E ( t )} ) , \qquad ( 3 )$$

$$β ( E ( t ) ) = {β}_{0} \cdot exp ( - \frac{b}{E ( t )} ) . \qquad ( 4 )$$

An electric charge generated by avalanche multiplication is temporarily held by first capacitor 12 and then discharged to power supply 13 via first resistor 11. A voltage applied to both ends of SPAD 10 and the magnitude of an internal electric field in the multiplication region inside SPAD 10 change in accordance with expressions (5) through (7).

$$[ Math . 3 ]$$

$$E ( t ) = \frac{V ( t )}{W} \qquad ( 5 )$$

$$V ( t ) = {V}_{0} - q \cdot \frac{n ( t ) + {N}_{c} ( t )}{C} . \qquad ( 6 )$$

$$\frac{{dN}_{c} ( t )}{dt} = \frac{2 {v}_{s , e}}{W} n ( t ) - \frac{{N}_{c}}{RC} . \qquad ( 7 )$$

The following expression (8) indicates voltage fluctuation ΔV from the initial state of the voltage.

### [Math. 4]

[Math. 4](t) (8)

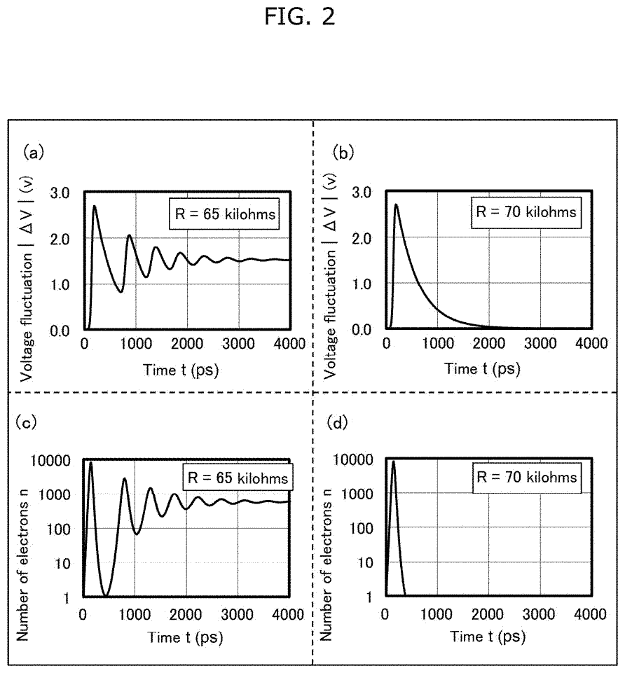

FIG. 2 is a diagram illustrating changes over time in voltage fluctuation calculated from the simulation described above and changes over time in the number of electrons in the depletion layer. The vertical axis in each of (a) and (b) in FIG. 2 indicates the absolute value of voltage fluctuation ΔV generated in a reverse bias voltage applied to SPAD 10. The vertical axis in each of (c) and (d) in FIG. 2 indicates the number of electrons n in the depletion layer. The horizontal axis in each of (a) through (d) in FIG. 2 indicates a change in time. FIG. 2 shows a simulation result when initial voltage V₀=29 V. The breakdown voltage of SPAD 10 obtained using the physical constants in FIG. 1C is 27.5 V and excess bias voltage Vₑₓ is 1.5 V. t=0 is a time when avalanche multiplication started and indicates a time when a pair of electron and hole was generated in the multiplication region. (a) in FIG. 2 shows a result obtained when resistance value R of first resistor 11=65 kilohms, and is an example of a simulation result in the case where quenching cannot be performed. An electric charge generated by the avalanche multiplication is accumulated in the capacitor at 100 ps to 200 ps so that voltage fluctuation ΔV is amplified by approximately 2.6 V. After that, voltage fluctuation ΔV decreases since the electric charge is discharged (recharged) via the resistor, and after ΔV=0.9 V at t=730 ns, voltage fluctuation ΔV increases again. After that, voltage fluctuation ΔV continues damped oscillation and finally indicates 1.5 V. Since voltage fluctuation ΔV does not return to 0, the avalanche multiplication does not stop and quenching is not achieved.

(b) in FIG. 2 shows a result obtained when resistance value R of first resistor 11=70 kilohms, and is an example of a simulation result in the case where quenching can be performed. After a voltage is amplified by approximately 2.6 V at t=200 ps, voltage fluctuation ΔV decreases due to recharge, and as can be seen from ΔV=0 at t=2 ns, avalanche multiplication stops and quenching is achieved. Thus, the maximum value of the voltage amplification in quenching in the photodetector according to the present disclosure is greater than excess bias voltage Vₑₓ.

According to changes over time in the number of electrons in the depletion layer when R=65 kilohms in (c) in FIG. 2, since the recharge keeps the number of electrons n(t) in the depletion layer to be always at least one while voltage fluctuation ΔV is decreasing, electrons that remained in the depletion layer cause avalanche multiplication again.

According to changes over time in the number of electrons in the depletion layer when R=70 kilohms in (d) in FIG. 2, since electrons disappear from the depletion layer at t=380 ps during recharge, there is no chance that avalanche multiplication will be caused again.

This simulation shows: a condition for achieving quenching with SPAD 10 is that carriers disappear from the depletion layer in a recharge process; and quenching can be surely achieved by setting a resistance value based on this condition. The simulation also shows that decreasing the resistance value within a range that satisfies this condition reduces a dead time and can achieve sensitivity enhancement and dynamic range extension.

Resistance value R of first resistor 11, which satisfies the condition for quenching, that is, carriers disappear from the depletion layer in a recharge process, can be analytically calculated as indicated below. When Vₑₓ is sufficiently less than V_{BD}, an impact ionization rate can be linearly approximated as in expressions (9) and (10) below.

$$[ Math . 5 ]$$

$$α ( E ) = {α}_{0} exp ( - \frac{a}{{E}_{BD} + δ E} ) = {α}_{0} exp ( - \frac{\frac{a}{{E}_{BD}}}{1 + ( \frac{δ E}{{E}_{BD}} )} ) ≃ α ( {E}_{BD} ) ( 1 + \frac{a}{{E}_{BD}^{2}} δ E ) , \qquad ( 9 )$$

$$β ( E ) = {β}_{0} exp ( - \frac{b}{{E}_{BD} + δ E} ) = {β}_{0} exp ( - \frac{\frac{b}{{E}_{BD}}}{1 + ( \frac{δ E}{{E}_{BD}} )} ) ≃ β ( {E}_{BD} ) ( 1 + \frac{b}{{E}_{BD}^{2}} δ E ) . \qquad ( 10 )$$

However, the following holds true.

$$[ Math . 6 ]$$

$$δ E = E ( t ) - {E}_{BD} , {E}_{BD} = \frac{{V}_{BD}}{W} . \qquad ( 11 )$$

That equations (12) and (13) hold true for V_{BD} is known from NPL 5.

$$[ Math . 7 ]$$

$$α ( {E}_{BD} ) + β ( {E}_{BD} ) = \frac{2}{W} \qquad ( 12 )$$

$${v}_{s , e} n = {v}_{s , h} p \qquad ( 13 )$$

Furthermore, when Vₑₓ is sufficiently less than V_{BD}, N_{C}(t)>>n(t) holds true, and therefore, expression (6) can be approximated to the following expression (14).

$$[ Math . 8 ]$$

$$V ( t ) \sim {V}_{0} - q \cdot \frac{{N}_{c} ( t )}{C} . \qquad ( 14 )$$

With the use of expressions (9) through (14), equations (1) and (2) can be rewritten as follows:

$$\begin{matrix}[ Math . 9 ] & \\ \frac{dn ( t )}{dt} = A δ {Ev}_{s , e} n ( t ) & ( 15 )\end{matrix}$$

However, the following expression (16) holds true.

$$\begin{matrix}[ Math . 10 ] & \\ A = \frac{a α ( {E}_{BD} ) + b β ( {E}_{BD} )}{{E}_{BD}^{2}} & ( 16 )\end{matrix}$$

Based on expression (14), number of electrons n(t) in the depletion layer can be expressed as follows:

$$\begin{matrix}[ Math . 11 ] & \\ n ( t ) = exp ( {\int }_{0}^{{T}_{0}} \frac{1}{{τ}_{Q} {V}_{ex}} ( {V}_{ex} - Δ V ( t ) ) dt ) & ( 17 )\end{matrix}$$

However, the following expression (18) expresses a time constant for voltage fluctuation caused by avalanche multiplication, and T₀ denotes a time when the number of electrons n(t) is the smallest.

$$\begin{matrix}[ Math . 12 ] & \\ {τ}_{Q} = \frac{W}{{Av}_{{s , e}_{}} {V}_{ex}} & ( 18 )\end{matrix}$$

Integration performed in the right-hand side in expression (17) is as follows:

$$\begin{matrix}[ Math . 13 ] & \\ n ( {T}_{0} ) = exp ( {\int }_{0}^{{T}_{0}} \frac{1}{{τ}_{Q}} ( 1 - \frac{Δ V ( t )}{{V}_{ex}} ) dt ) ∼ exp ( \frac{1}{{τ}_{Q}} ( {t}_{BD} - \frac{1}{2} RC ln ( 2 ) ) ) & ( 19 )\end{matrix}$$

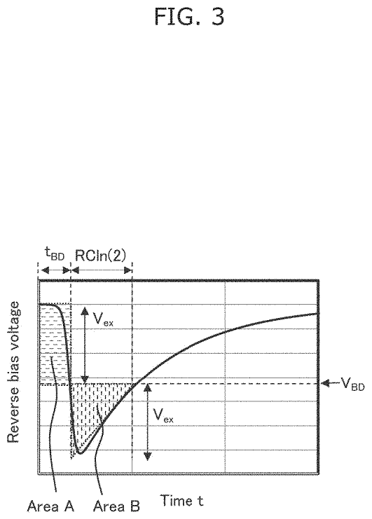

Integration in expression (19) is approximately performed using FIG. 3. Specifically, FIG. 3 is a diagram illustrating changes over time in reverse bias voltage V when avalanche multiplication occurs. A value resulting from dividing the difference between the area of area A and the area of area B by T_{Q}Vₑₓ is an integral value in the right-hand side in expression (17), which utilizes that area A can be approximated as a quadrilateral with height Vₑₓ and width t_{BD} while area B can be approximated as a triangle with vertical height Vₑₓ and base RCIn(2). Formula (20) indicated below, however, expresses a time from the start of the avalanche multiplication until ΔV=Vₑₓ.

$$\begin{matrix}[ Math . 14 ] & \\ {t}_{BD} ∼ {τ}_{Q} ln ( \frac{{CV}_{ex} W}{q {v}_{s , e} {τ}_{Q}} ) & ( 20 )\end{matrix}$$

Since that a value resulting from expression (19) is less than 1 is a condition for quenching, a prerequisite for resistance value R of first resistor 11 is as follows:

$$\begin{matrix}[ Math . 15 ] & \\ R > \frac{2 {τ}_{Q} ln ( \frac{C {V}_{e x} W}{q {v}_{s , e} {τ}_{Q}} )}{C ln ( 2 )} = \frac{2 {E}_{BD}^{2} ln ( \frac{C {V}_{ex}^{2} W ( a α ( {E}_{BD} ) + b β ( {E}_{BD} ) )}{{qE}_{BD}^{2}} )}{( a α ( {E}_{BD} ) + b β ( {E}_{BD} ) ) {v}_{s , e} {CV}_{e x} ln ( 2 )} & ( 21 )\end{matrix}$$

A condition defined by expression (19) is approximately equivalent to a condition that a time required for a voltage to come back through a recharge is shorter than a time from the start of avalanche multiplication until all of electric charge is discharged. Resistance R calculated by substituting the physical constants listed in FIG. 1C into the right-hand side of expression (21) is 68 kilohms, which matches the results shown in FIG. 2. A dead time obtained by expression (21) is RC which is the time of recharge by first resistor 11, and expression (22) below holds true.

$$\begin{matrix}[ Math . 16 ] & \\ {t}_{dead} > \frac{2 {τ}_{Q} ln ( \frac{C {V}_{e x} W}{{qv}_{s , e} {τ}_{Q}} )}{ln ( 2 )} = \frac{2 {E}_{BD}^{2}}{( a α ( {E}_{BD} ) + b β ( {E}_{BD} ) ) {v}_{s , e} {V}_{e x}} \frac{ln ( \frac{C {V}_{e x}^{2} W ( a α ( {E}_{BD} ) + b β ( {E}_{BD} ) )}{{qE}_{BD}^{2}} )}{ln ( 2 )} & ( 22 )\end{matrix}$$

According to this, a dead time depends on (i) excess bias voltage Vₑₓ, (ii) capacitance C of first capacitor 12, (iii) depletion layer width W, and (iv) breakdown voltage V_{BD}. Since the dead time is approximately inversely proportional to excess bias voltage Vₑₓ, in particular, increasing Vₑₓ can reduce the dead time even more. If resistance value R of first resistor 11 as a quenching resistor, which is derived from the present simulation, is used, the dead time can be reduced as less as 2 ns in the example in FIG. 2, for example. In FIG. 7.4 of NPL 1, a dead time, that is, a period denoted as Re-charge can be read as approximately 300 ns. According to the present disclosure, the dead time can be reduced to one hundredth or less of the dead time according to NPL 1.

So far, analysis is performed based on the values of impact ionization rates shown in NPL 3, but different values may be indicated depending on literature since the values of impact ionization rates vary depending on the temperature, internal electric field, and device structure of SPAD 10. In this case, the notation of expression (21) may be changed. For example, an impact ionization rate according to NPL 4 is as indicated in expression (9-1) below.

$$\begin{matrix}[ Math . 17 ] & \\ {α}_{i} ( F , T ) = \frac{E}{{α}_{i} ( T ) + {b}_{i} ( T ) exp [ \frac{{d}_{i} ( T )}{[ {c}_{i} ( T ) + E ]} ]} & \text{(9-1)}\end{matrix}$$

However, the subscripts i are expressed as e when carriers are electrons, and are expressed as h when the carriers are holes. In this case, expression (21) may be rewritten into expression (21-1) below.

$$\begin{matrix}[ Math . 18 ] & \\ R > \frac{2 {E}_{BD}^{2} ln ( \frac{C {V}_{ex}^{2} W}{q} B )}{( aα ( {E}_{BD} ) + b β ( {E}_{BD} ) ) {v}_{s , e} {CV}_{ex} ln ( 2 )} . & \text{(21-1)}\end{matrix}$$

However, expression (21-2) below holds true.

$$\begin{matrix}[ Math . 19 ] & \\ B = \frac{{b}_{e} ( T ) exp [ \frac{{d}_{e} ( T )}{[ {c}_{e} ( T ) + {E}_{BD} ]} ]}{{( {a}_{e} ( T ) + {b}_{e} ( T ) exp [ \frac{{d}_{e} ( T )}{[ {c}_{e} ( T ) + {E}_{BD} ]} ] )}^{2}} \frac{{d}_{e} ( T )}{{( {c}_{e} ( T ) + {E}_{BD} )}^{2}} + \frac{{b}_{h} ( T ) exp [ \frac{{d}_{h} ( T )}{[ {c}_{h} ( T ) + {E}_{BD} ]} ]}{{( {a}_{h} ( T ) + {b}_{h} ( T ) exp [ \frac{{d}_{h} ( T )}{[ {c}_{h} ( T ) + {E}_{BD} ]} ] )}^{2}} \frac{{d}_{h} ( T )}{{( {c}_{h} ( T ) + {E}_{BD} )}^{2}} & \text{(21-2)}\end{matrix}$$

In this way, a prerequisite to be satisfied by resistance value R of first resistor 11 as a quenching resistor may be different depending on a reference document and is not limited by temperature, electric field, and device structure.

### Embodiment 1

Photodetector 1 according to Embodiment 1 will be described with reference to FIG. 4 through FIG. 7.

FIG. 4 is a diagram illustrating a circuit example of photodetector 1 according to Embodiment 1. This photodetector 1 includes SPAD 10, first resistor 11 connected in series to the cathode of SPAD 10, first capacitor 12 connected in parallel to SPAD 10, and output unit 14 that outputs the cathode voltage of SPAD 10. One end of first resistor 11 is connected to first power supply V1. The anode of SPAD 10 is connected to second power supply V2. First capacitor 12 may have the parasitic capacitance of SPAD 10, may be a capacitor element separate from SPAD 10, or the both.

Since a reverse bias voltage greatly fluctuates due to avalanche multiplication when light is incident on SPAD 10, it is possible to output information about the presence or absence of incident photons and the number of incident photons. First capacitor 12 and first resistor 11 may be formed through an LSI process or included in an external circuit element. Both ends of first capacitor 12 do not need to be connected to both ends of SPAD 10, and one end of first capacitor 12 may be connected to one end of SPAD 10. In this case, what contribute to capacitance C in expression (21) are: a capacitor connected to an end at which first resistor 11 is connected to SPAD 10; and first capacitor 12 connected to the cathode of SPAD 10 in FIG. 4.

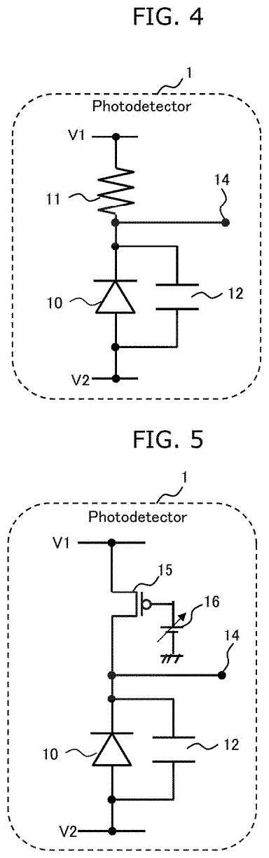

FIG. 5 is a diagram illustrating a variation of photodetector 1 according to Embodiment 1. The configuration of photodetector 1 in FIG. 5 is different from the configuration of photodetector 1 in FIG. 4 in the following points: first resistor 11 is the channel resistance of first transistor 15 which is a transistor including a p-type channel; and photodetector 1 includes first variable power supply 16. The following focuses on the differences.

First variable power supply 16 supplies a variable voltage as the gate voltage of first transistor 15. The channel resistance of first transistor 15 determined by the gate voltage is set to satisfy a prerequisite for a quenching resistor, i.e., expression (21). According to the configuration described herein, first transistor 15 is connected to the cathode of SPAD 10, but the conductivity type of first transistor 15 is non-limiting and an n-type conductivity type transistor may be connected to the anode of SPAD 10, for example.

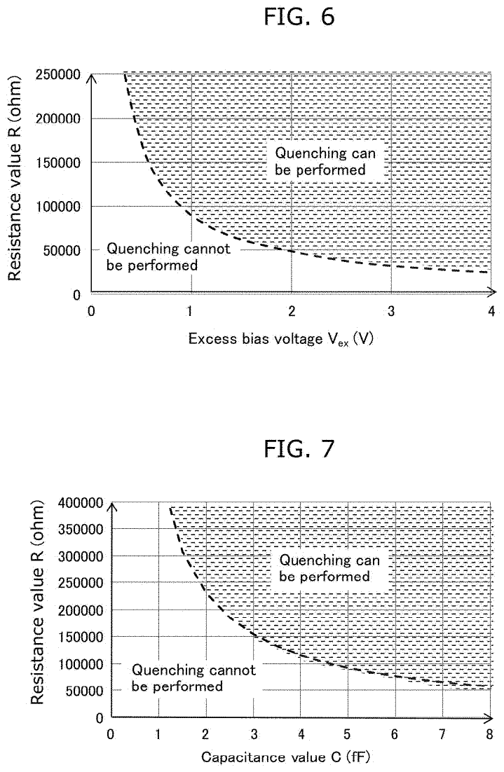

Next, how to decide conditions for a quenching resistor will be described with reference to FIG. 6 and FIG. 7. A prerequisite for quenching is determined by (i) the resistance value of a quenching resistor, (ii) capacitance C of SPAD 10, (iii) excess bias voltage Vₑₓ, (iv) depletion layer width W, and (v) breakdown voltage V_{BD}, and (i) through (v) described above are set to satisfy expression (21). FIG. 6 illustrates one example of a chart illustrating whether quenching can be performed or not with respect to excess bias voltage Vₑₓ and resistance value R of first resistor 11. The dotted line is the result of calculation using expression (21), and conditions shown in FIG. 1C are used for constants other than Vₑₓ and R. In the upper right area above the dotted line, quenching can be performed. In the lower left area below the dotted line, however, quenching cannot be performed and SPAD 10 continues avalanche multiplication.

FIG. 7 illustrates one example of a chart illustrating whether quenching can be performed or not with respect to capacitance C of first capacitor 12 and resistance value R of first resistor 11. The dotted line is the result of calculation using expression (21), and conditions shown in FIG. 1C are used for constants other than C and R. In the upper right area above the dotted line, quenching can be performed. In the lower left area below the dotted line, however, quenching cannot be performed and SPAD 10 continues avalanche multiplication.

FIG. 6 and FIG. 7 each illustrate the correspondence, which is required for quenching, between circuit constants and the device structure of SPAD 10. Particularly, by setting resistance value R of first resistor 11 to obtain a calculation result closer to the dotted line in FIG. 6 or FIG. 7, SPAD 10 and a quenching circuit each with a short dead time can be achieved.

As described above, photodetector 1 according to Embodiment 1 includes SPAD 10, and first resistor 11 connected in series to SPAD 10. In a recharge time in which an electric charge is discharged from SPAD 10 via first resistor 11, an electric charge disappears from the multiplication region in SPAD 10.

An excess bias voltage applied to SPAD 10 may be less than the breakdown voltage of SPAD 10, and resistance value R of first resistor 11 may satisfy expression (21) presented above. In expression (21), E_{BD} denotes an electric field strength inside SPAD 10, C denotes a capacitance including the parasitic capacitance of SPAD 10, Vₑₓ denotes an excess bias voltage, i.e., the difference between a reverse bias voltage applied to SPAD 10 and the breakdown voltage, W denotes the depletion layer width of SPAD 10, α(E_{BD}) denotes an electron impact ionization rate under electric field strength E_{BD}, β(E_{BD}) denotes a hole impact ionization rate under electric field strength E_{BD}, a denotes the coefficient of the electron impact ionization rate, b denotes the coefficient of the hole impact ionization rate, q denotes an elementary charge, and v_{s,e} denotes an electron saturation velocity.

### Embodiment 2

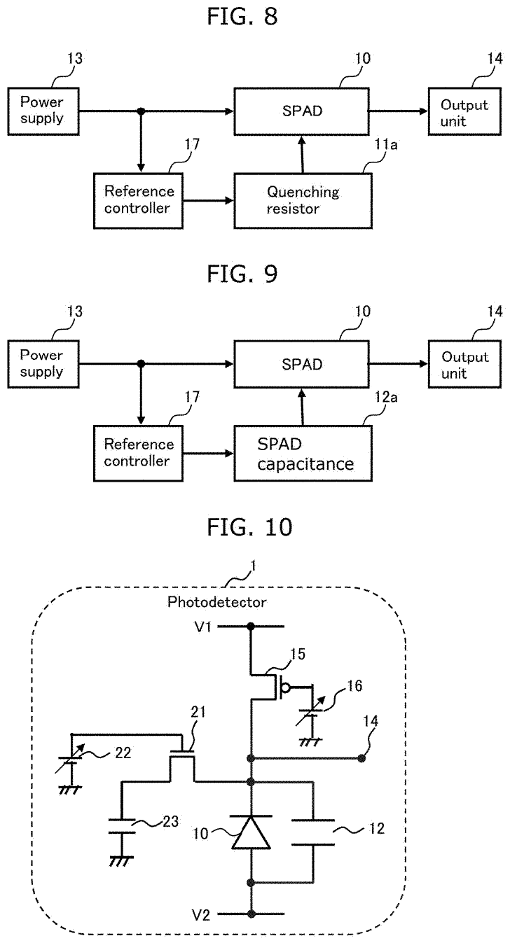

FIG. 8 is a block diagram illustrating a configuration example of a control system including photodetector 1 according to Embodiment 2. The control system includes power supply 13, SPAD 10, quenching resistor 11a, reference controller 17, and output unit 14. SPAD 10 and quenching resistor 11a are equivalent to photodetector 1 in FIG. 5. Quenching resistor 11a is equivalent to, for example, first transistor 15 and first variable power supply 16 in FIG. 5. First variable power supply 16 outputs a variable voltage to the gate of first transistor 15 in accordance with control performed by reference controller 17.

Reference controller 17 refers to the voltage of power supply 13 and controls resistance value R of quenching resistor 11a in accordance with expression (21). Specifically, reference controller 17 includes, for instance, a central processing unit (CPU) and calculates excess bias voltage Vₑₓ based on the difference between a breakdown voltage recorded in advance and the power supply voltage. The gate voltage of first transistor 15 is controlled in accordance with the calculated excess bias voltage Vₑₓ. The gate voltage may be controlled so that the channel resistance of first transistor 15 is approximately inversely proportional to excess bias voltage Vₑₓ. This can reduce resistance value R of quenching resistor 11a and thus reduce a dead time even more irrespective of the value of a reverse bias voltage. Since photon detection efficiency (PDE) increases as excess bias voltage Vₑₓ increases and decreases as excess bias voltage Vₑₓ decreases, particularly in SPAD 10, the reverse bias voltage may therefore be controlled in accordance with the amount of incident light. By setting excess bias voltage Vₑₓ to be low under the condition that the amount of incident light is large and to be high under the condition that the amount of incident light is small, for example, photodetector 1 with a wide dynamic range can be achieved. In this case, using the control system according to Embodiment 2 can reduce a dead time even more and also extend a dynamic range.

FIG. 9 is a block diagram illustrating another configuration example of the control system including photodetector 1 according to Embodiment 2. In the configuration in FIG. 9, the control target of reference controller 17 is changed from quenching resistor 11a to SPAD capacitor 12a, as compared with the configuration in FIG. 8.

Reference controller 17 in FIG. 9 reduces SPAD capacitance 12a when the reverse bias voltage of SPAD 10 is high and increases SPAD capacitance 12a when the reverse bias voltage of SPAD 10 is low. With this, a dead time can be reduced irrespective of the value of the reverse bias voltage.

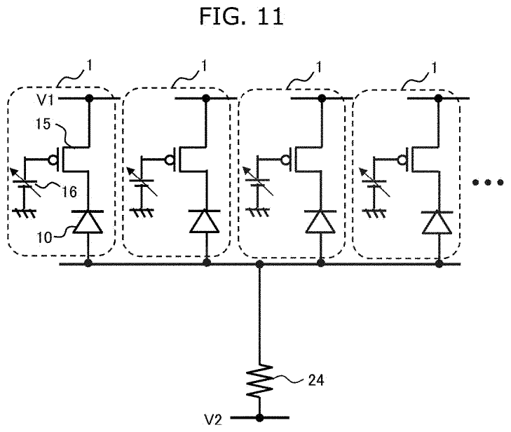

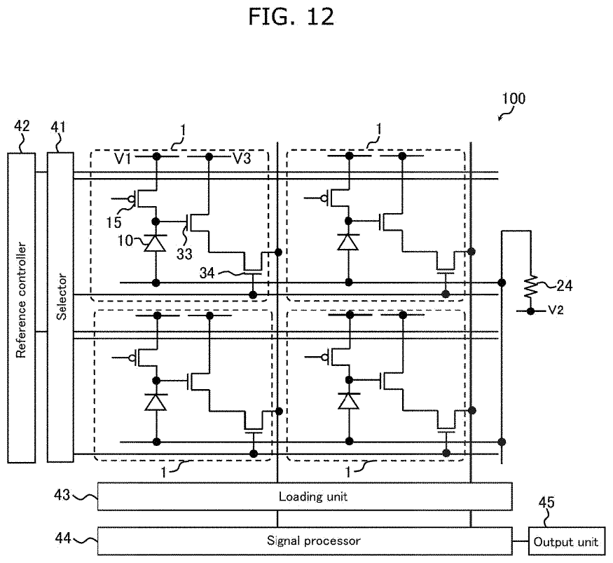

FIG. 10 is a circuit diagram of photodetector 1 that achieves the control system in FIG. 8 or FIG. 9. The configuration in FIG. 10 is different from the configuration in FIG. 5 in that second transistor 21, second variable power supply 22, and second capacitor 23 are added. The following focuses on the difference.

Second transistor 21 which is an n-type transistor is connected to the cathode of SPAD 10. Second capacitor 23 is connected to an end of second transistor 21 opposite to the end at which second transistor 21 is connected to the cathode of SPAD 10. Second variable power supply 22 is connected to the gate of second transistor 21.

In the case where photodetector 1 in FIG. 10 is included in the control system in FIG. 8, a channel resistance is decreased by reducing the gate voltage of first transistor 15 when the reverse bias voltage of SPAD 10 is high, and the channel resistance is increased by increasing the gate voltage of first transistor 15 when the reverse bias voltage of SPAD 10 is low.

In the case where photodetector 1 in FIG. 10 is included in the control system in FIG. 9, when the reverse bias voltage of SPAD 10 is high, the capacitance of SPAD 10 is decreased by bringing second transistor 21 into a non-conducting state, and when the reverse bias voltage of SPAD 10 is low, the capacitance of SPAD 10 is increased by bringing second transistor 21 into a conducting state. With this, a dead time can be minimized irrespective of the value of excess bias voltage Vₑₓ. Both of quenching resistor 11a and SPAD capacitance 12a may be controlled at the same time. At least one of the following parameters is referred to and at least one parameter other than at least one of the following parameters referred to may be controlled: (i) the resistance value of a quenching resistor, (ii) capacitance C of SPAD 10, (iii) excess bias voltage Vₑₓ, (iv) depletion layer width W, and (v) breakdown voltage V_{BD}. Parameters (i) through (v) described above may be controlled in accordance with temperature. Since the channel resistance of first transistor 15 varies depending on temperature, the gate voltage of first transistor 15 may be controlled according to temperature. Particularly, if excess bias voltage Vₑₓ is same, a dead time is same. It is therefore recommended to control the gate voltage of first transistor 15 so that the channel resistance of first transistor 15 hardly varies depending on temperature. With this, a dead time can be reduced irrespective of temperature.

As described above, photodetector 1 according to Embodiment 2 includes reference controller 17, and reference controller 17 refers to at least one of the following five parameters and controls at least one parameter other than at least one of the following five parameters referred to: (i) resistance value R of first resistor 11; (ii) capacitance C including the parasitic capacitance of SPAD 10; (iii) excess bias voltage Vₑₓ; (iv) depletion layer width W of SPAD 10; and (v) breakdown voltage V_{BD} of SPAD 10.

First resistor 11 may be a variable resistor and reference controller 17 may decrease the resistance value of first resistor 11 as the excess bias voltage increases.

First resistor 11 may include first transistor 15, and the resistance value of first resistor 11 may correspond to the channel resistance of first transistor 15.

Capacitance C including the parasitic capacitance of SPAD 10 may be variable, and reference controller 17 may decrease the capacitance value of capacitance C as the excess bias voltage increases.

Photodetector 1 may include: second transistor 21 having one end at which SPAD 10 is connected to first transistor 15; and second capacitor 23 at the other end of second transistor 21. Reference controller 17 may refer to the excess bias voltage of SPAD 10, and control the gate voltage of second transistor 21.

### Embodiment 3

FIG. 11 is a diagram illustrating a circuit example of a photodetector array according to Embodiment 3. The photodetector array includes N photodetectors 1 in parallel, where N is a natural number of 2 or greater, and also includes second resistor 24. Each of N photodetectors 1 includes SPAD 10, first transistor 15, and first variable power supply 16. Second resistor 24 is connected between SPAD 10 and second power supply V2 at an end to which photodetector 1 is connected, i.e., an end to which SPAD 10 is connected. In this case, second resistor 24 is required to discharge electric charges generated by all of N SPADs 10 in a short time less than the recharge time of SPAD 10. In other words, time constant rNC defined by resistance value r of second resistor 24 is required to be less than recharge time RC of SPAD 10 defined by resistance value R of first resistor 11. Stated differently, the following expression is required to be satisfied.

$$\begin{matrix}[ Math . 20 ] & \\ r < \frac{R}{N} & ( 23 )\end{matrix}$$

Based on expression (21), resistance value r of second resistor 24 may be derived using the following expression.

$$\begin{matrix}[ Math . 21 ] & \\ r < \frac{2 {τ}_{Q} ln ( \frac{{CV}_{ex} W}{{qv}_{s , e} {τ}_{Q}} )}{NC ln ( 2 )} & ( 24 )\end{matrix}$$

With this, the parallel connection of a plurality of SPADs 10 will not deteriorate quenching properties. Photodetector 1 may be used in, for example, an image sensor or a photon counter in which a plurality of photodetectors 1 are arranged in an array.

Although output unit 14 is omitted in FIG. 11, each of photodetectors 1 may include output unit 14 or an output unit may be shared among N photodetectors 1. In the case where each of photodetectors 1 includes output unit 14, a connection portion connecting the cathode of SPAD 10 and first transistor 15 may be an output node. In the case where an output unit is shared among N photodetectors 1, a connection portion connecting the anodes of SPADs 10 and second resistor 24 may be an output unit.

FIG. 12 is a diagram illustrating a circuit example of solid-state imaging device 100 according to Embodiment 3. Solid-state imaging device 100 in FIG. 12 includes, in addition to a plurality of photodetectors 1, reference controller 42, selector 41, loading unit 43, signal processor 44, a signal output line, and output unit 45. Moreover, photodetector 1 in FIG. 12 differs from photodetector 1 in FIG. 11A in that third power supply V3, third transistor 33, and fourth transistor 34 are added. The following focuses on the difference.

Third transistor 33 is an amplification transistor that outputs, to the cathode of SPAD 10, a voltage that is in accordance with the amount of electric charge. Specifically, when fourth transistor 34 is ON, third transistor 33 together with the load (e.g., constant current source) of loading unit 43 forms a source follower.

Fourth transistor 34 is a switching transistor for selection that turns ON in accordance with a selection control signal from selector 41.

Reference controller 42, selector 41, and signal processor 44 may be formed on a semiconductor substrate, and these elements altogether may be referred to as a peripheral circuit portion. The cathode of SPAD 10 is connected to the gate of third transistor 33 and the amount of current varies in accordance with the cathode voltage of SPAD 10. Selector 41 is connected to the gate of fourth transistor 34 and selects at least one photodetector 1 that outputs a signal. The signal from selected photodetector 1 is output to signal processor 44 via the signal output line. The signal processed by signal processor 44 is output as numerical value data or image data from output unit 45. Output unit 45 is, for example, a display. With this, output from photodetector 1 can be output in a format such as an image format. Although the conductivity type of third transistor 33 and fourth transistor 34 is described to be p type in FIG. 12, the conductivity type may be n type.

Next, the device structure of a solid-state imaging device in FIG. 12 will be described.

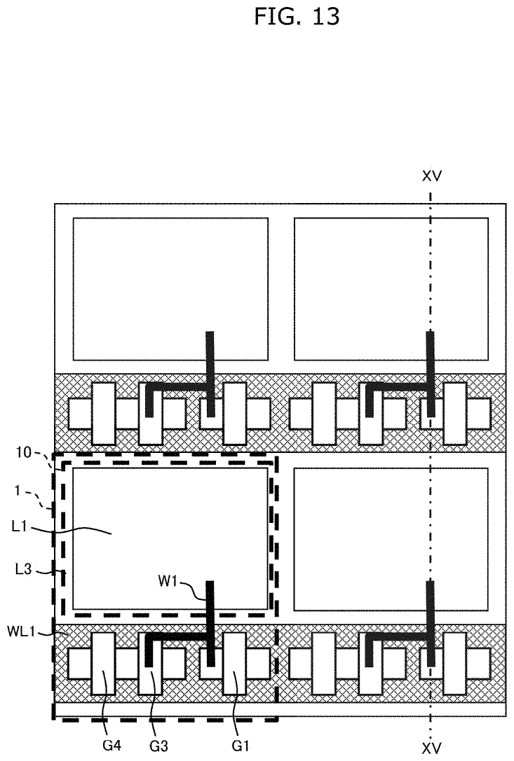

FIG. 13 through FIG. 15 each illustrate the device structures of a photodetector array and a solid-state imaging device according to Embodiment 3. FIG. 13 is a diagram illustrating a layout example of a plan view of solid-state imaging device 100 in FIG. 12. The structure of 2×2 pixels is illustrated in FIG. 13. As can be seen from FIG. 13, solid-state imaging device 100 includes a plurality of photodetectors 1, and each of photodetectors 1 includes SPAD 10, first well WL1, first wire W1, gate G1 of first transistor 15, gate G3 of third transistor 33, gate G4 of fourth transistor 34, and first semiconductor layer L1 of the first conductivity type and third semiconductor layer L3 of the second conductivity type that are included in SPAD 10. Wires other than first wire W1, semiconductor layers other than first semiconductor layer L1, third semiconductor layer L3, and first well WL1 are omitted for the sake of viewability. First transistor 15, third transistor 33, and fourth transistor 34 are disposed in first well WL1. First semiconductor layer L1 is connected to the drain of first transistor 15 and gate G3 of third transistor 33 by first wire W1. The source of first transistor 15 is connected to first power supply V1.

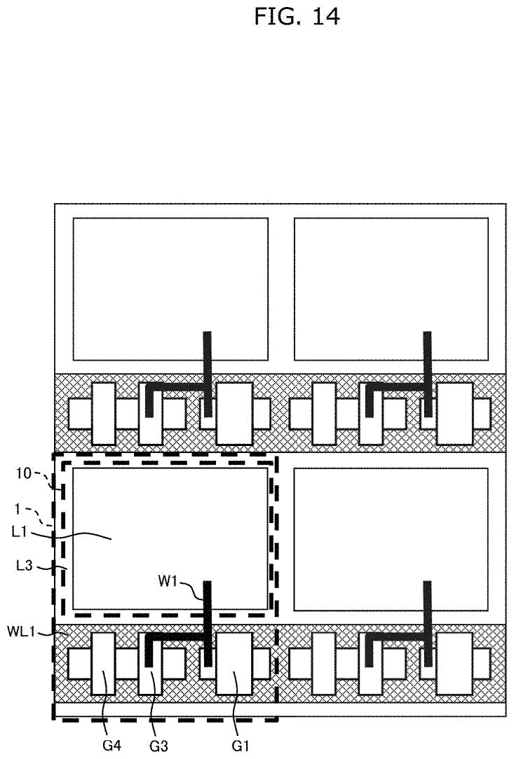

FIG. 14 is a diagram illustrating a variation of the layout of the plan view of solid-state imaging device 100 according to Embodiment 3. In the layout in FIG. 14, the area of gate G1 of first transistor 15 is greater than the area of gate G3 of third transistor 33 or gate G4 of fourth transistor 34, as compared with FIG. 13.

Thus, the area of gate G1 of first transistor 15 is greater than the area of the gate of other transistor, i.e., third transistor 33 or fourth transistor 34. With this, variance in the threshold voltage of first transistor 15 can be inhibited and variance in the channel resistance of first transistor 15 can be inhibited. This can increase even more the number of photodetectors 1 arranged in an array while satisfying the condition defined by expression (21), and thus extends a dynamic range.

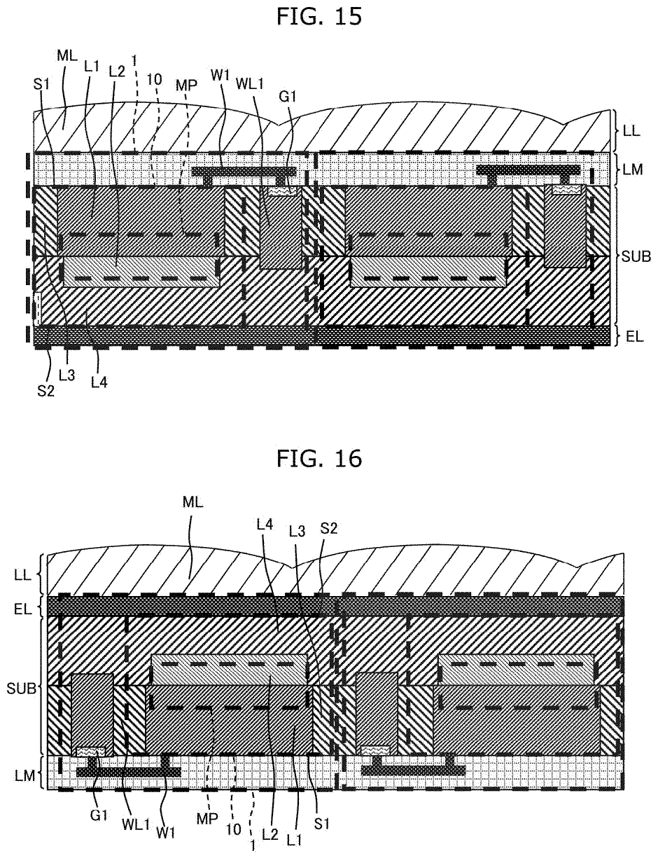

FIG. 15 is a diagram illustrating an example of a cross-sectional configuration of solid-state imaging device 100 taken along the line XV-XV in FIG. 13. Solid-state imaging device 100 includes semiconductor substrate SUB, wire layer LM disposed in contact with first principal surface S1 of semiconductor substrate SUB, electrode EL disposed in contact with second principal surface S2 of semiconductor substrate SUB, and lens layer LL in contact with the top of wire layer LM. A light emission surface is on the first principal surface S1 side. As can be seen from the cross section in FIG. 15, second semiconductor layers L2 of the second conductivity type and fourth semiconductor layer L4 of the second conductivity type are included in semiconductor substrate SUB, in addition to the elements illustrated in FIG. 13. SPAD 10 includes first semiconductor layer L1, second semiconductor layer L2, third semiconductor layer L3, and fourth semiconductor layer L4, and the vicinity of the interface between first semiconductor layer L1 and second semiconductor layer L2 is multiplication region MP. Second semiconductor layers L2 are connected through semiconductor substrate SUB or fourth semiconductor layer L4. Wires other than first wire W1 are omitted in wire layer LM. Lens layer LL includes micro lens ML. Voltage application to the anode of SPAD 10, i.e., voltage application to second semiconductor layer L2 may be performed via electrode EL. In this case, since second resistor 24 includes a junction between semiconductor substrate SUB and electrode EL, it is preferable that the resistance of the junction between semiconductor substrate SUB and electrode EL is low. In the case where semiconductor substrate SUB is made of silicon, for example, Ag, Pt, Ti, Au, etc. may be used for the electrode materials of semiconductor substrate SUB. This can reduce the value of second resistor 24 and extend a dynamic range.

Third semiconductor layer L3 functions to separate first semiconductor layer L1 from another first semiconductor layer L1 and separate first semiconductor layer L1 from first well WL1. At least a portion of a region, of third semiconductor layer L3, which contacts first principal surface S1 may be depleted. This can reduce the distance between first semiconductor layers L1 and the distance between first semiconductor layer L1 and first well WL1, and reduce more the size of photodetector 1. A contact or trench need not be placed in a region, of a region in which third semiconductor layer L3 is disposed, which contacts first principal surface S1. This can reduce defects in third semiconductor layer L3 and reduce dark current.

Although FIG. 15 presents second semiconductor layer L2, third semiconductor layer L3, and fourth semiconductor layer L4 as different semiconductor layers for the sake of convenience, these semiconductor layers need not necessarily be formed, for instance, using different impurity concentrations or by implantation of different impurities, and may be formed, for example, using the same impurity concentration.

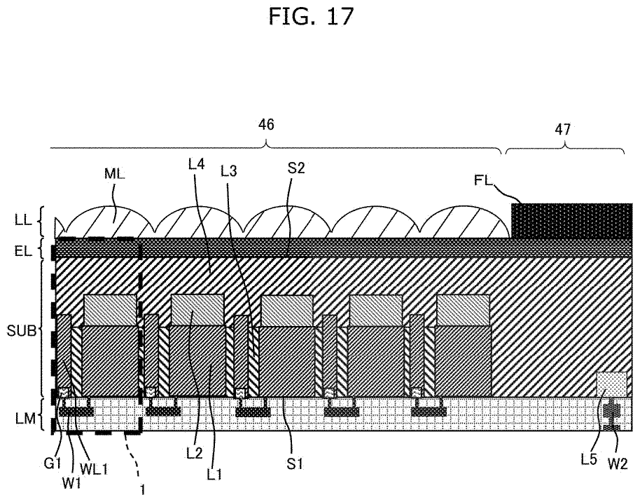

FIG. 16 is a diagram illustrating a variation of the cross-sectional configuration of solid-state imaging device 100 taken along the line XV-XV in FIG. 13. In the variation in FIG. 16, the location of a light emission surface is changed from the first principal surface S1 side to the second principal surface S2 side, as compared with the configuration in FIG. 15. Lens layer LL is disposed to be in contact with the top of electrode EL. This can prevent light reflection by wires and enhance sensitivity. It is recommended herein that a material with high light transmittance be used for electrode EL. In the case where the wavelength range of light to be used ranges from visible light to near infrared rays, for example, an indium tin oxide (ITO) for instance may be used for the material of electrode EL.

FIG. 17 is a diagram illustrating another example of a cross-sectional configuration of solid-state imaging device 100 according to Embodiment 3. FIG. 17 illustrates a broader range of a cross section compared with a cross section in FIG. 16. Solid-state imaging device 100 includes: light reception area 46 in which a plurality of photodetectors 1 are provided; and contact region 47 located outside light reception area 46. Contact region 47 includes filter FL, second wire W2, and fifth semiconductor layer L5. A voltage is applied to the anode of SPAD 10 via second wire W2, fifth semiconductor layer L5, fourth semiconductor layer L4, and electrode EL. In FIG. 17, filter FL is provided in a region, of contact region 47, which contacts second principal surface S2 so that incident light does not transmit. This can prevent false positives caused by light incident on contact region 47. In FIG. 17, second resistor 24 includes second wire W2, fifth semiconductor layer L5, fourth semiconductor layer L4, and electrode EL. In the example in FIG. 17, electrode EL need not necessarily be provided. In the case where electrode EL is not provided, a decrease in light sensitivity due to light reflection and light absorption by electrode EL can be prevented and sensitivity can be enhanced. The impurity concentrations of fourth semiconductor layer L4 and fifth semiconductor layer L5 may be increased in order to reduce a diffuse resistance, which makes it easier to satisfy expression (23) or expression (24) that is the prerequisite of second resistor 24. Particularly, the impurity concentration of fourth semiconductor layer L4 may be increased from the first principal surface S1 side toward the second principal surface S2 side. With this, an electric charge generated in fourth semiconductor layer L4 is transferred to multiplication region MP due to the built-in potential of fourth semiconductor layer L4, and sensitivity can be enhanced. Although FIG. 17 illustrates a configuration in which light is emitted from second principal surface S2, light may be emitted from first principal surface S1.

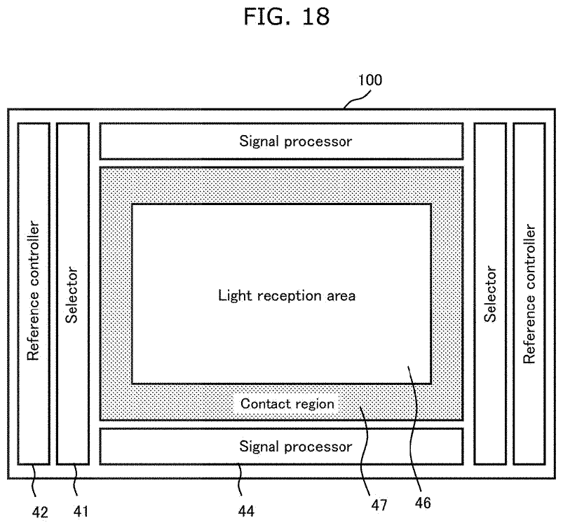

FIG. 18 is a schematic layout diagram of a plan view of the whole of solid-state imaging device 100 in FIG. 17. As can be seen from FIG. 18, solid-state imaging device 100 includes a chip, and the chip includes light reception area 46, contact region 47, reference controller 42, selector 41, and signal processor 44. Contact region 47 is disposed adjacent to light reception area 46 and is disposed in such a manner to surround light reception area 46. Reference controller 42, selector 41, and signal processor 44 are disposed on an outer circumference outside contact region 47. With light reception area 46 and contact region 47 being disposed adjacent to each other, the value of second resistor 24 can be reduced even more and a photodetector array with a wide dynamic range can be achieved. As long as expression (23) or expression (24) which defines a condition for second resistor 24 is satisfied, contact region 47 may be disposed outside any one of reference controller 42, selector 41, and signal processor 44.

As described above, the photodetector array according to Embodiment 3 includes N photodetectors each of which is photodetector 1 described above, where N is an integer of 2 or greater. N series circuits included in N photodetectors 1 are connected in parallel. Each of the N series circuits includes SPAD 10 and first resistor 11 that are connected in series. N ends on the SPAD 10 side are connected to each other, where the N ends are one ends of the N series circuits. The photodetector array further includes second resistor 24 that is connected to the N ends connected to each other and is connected in series to the N photodetectors. The resistance value of second resistor 24 is less than one N-th of the resistance value of first resistor 11.

N SPADs 10 may be disposed on a single semiconductor substrate, and the N ends may be connected to each other via the single semiconductor substrate.

A voltage may be applied, via an electrode disposed in contact with a second principal surface, to the N ends connected to each other, where the second principal surface is a principal surface of the semiconductor substrate and faces the N ends connected to each other.

The photodetector array may further include: a light reception area in which the N photodetectors are disposed; a contact region disposed outside the light reception area; and a second wire disposed in contact with a first principal surface that is a principal surface of the semiconductor substrate on a side opposite to a second principal surface, where the second principal surface is a principal surface of the semiconductor substrate and faces the N ends connected to each other. A voltage may be applied, via the second wire, to the N ends connected to each other.

The photodetector array may further include a peripheral circuit portion that performs control or signal processing on the N photodetectors. The contact region may be disposed between the light reception area and the peripheral circuit portion.

Each of the N photodetectors may include at least two transistors including first transistor 11. First resistor 11 may be the channel resistance of first transistor 15. First transistor 15 may have a gate area greater than the gate area of other transistor included in the photodetector.

The photodetector array according to Embodiment 3 includes M photodetectors 1 each of which is photodetector 1 described above, where M is an integer of 2 or greater. M photodetectors 1 are connected to each other at one end of SPAD 10. Third resistor 31 and third capacitor 32 are connected at the one end of SPAD 10. First resistor 11 is first transistor 15. The resistance value r′ of third resistor 31 satisfies expression (25).

First transistor 15 may be in a conducting state in a reset period for resetting SPAD 10, and in a non-conducting state in an exposure period for detecting light incident on SPAD 10.

First transistor 15 may include a channel that may have a conductivity type same as the conductivity type of an end of SPAD 10 at which first transistor 15 is connected.

The capacitance value of third capacitor 32 may be greater than the capacitance of SPAD 10.

### Application Example of Photodetector or Photodetector Array

Hereinafter, an application example of a photodetector or a photodetector array according to the present disclosure will be described with reference to some of the drawings.

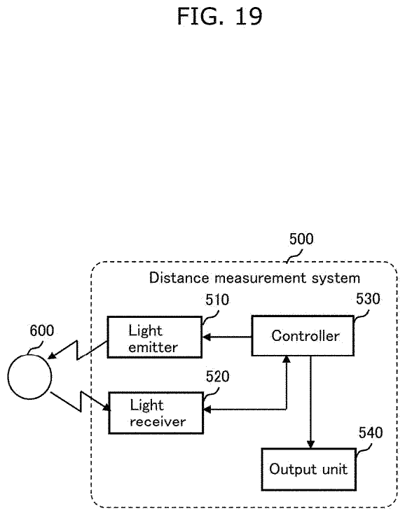

FIG. 19 illustrates an application example of a photodetector or a photodetector array according to the present disclosure, and is a block diagram illustrating one example of a distance measurement system using photodetector 1 or a photodetector array according to the present disclosure.

Distance measurement system 500 according to the application example of photodetector 1 or the photodetector array includes light emitter 510 that emits pulse light, light receiver 520 that receives reflected pulse light, controller 530 that controls light emitter 510 and light receiver 520, and output unit 540 that outputs a signal from light receiver 520.

Light emitter 510, which includes a light-emitting device such as a light-emitting diode, generates pulse light based on a control signal from controller 530 and emits the pulse light toward measurement target 600. Light emitter 510 may be a diffuse light source and measurement target 600 may be plural.

Light receiver 520 is photodetector 1, the photodetector array, or solid-state imaging device 100 according to the embodiment described above, and receives pulse light reflected by measurement target 600. Light receiver 520 may include an optical system such as a lens and form an image on photodetector 1 or the photodetector array.

Controller 530 includes, for instance, a central processing unit (CPU) and controls both light emitter 510 and light receiver 520 so that they operate in synchronization. Controller 530 calculates the distance to measurement target 600 by measuring a time from when pulse light is reflected from measurement target 600 until when the reflected pulse light returns to light receiver 520, based on a control signal to light emitter 510 and an output signal from light receiver 520.

Output unit 540 outputs the distance to measurement target 600 calculated by controller 530 in a numerical value data format or an image format. Output unit 540 normally includes a display, e.g., a liquid crystal display or an organic EL display.

Distance measurement system 500 according to the present embodiment is a distance measurement system using a so-called time of flight (TOF) method.

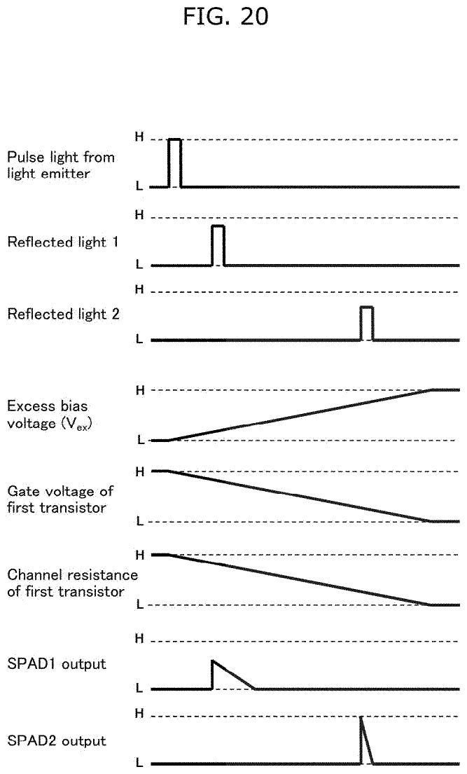

FIG. 20 is a diagram illustrating an example of a timing chart for distance measurement system 500 in FIG. 19. The timing chart includes pulse light from a light emitter, reflected light 1, reflected light 2, excess bias voltage Vₑₓ, the gate voltage of first transistor 15, 25 the channel resistance of first transistor 15, SPAD 1 output, and SPAD 2 output. In the timing chart, the vertical axis indicates: light intensities for pulse light from the light emitter, reflected light 1, and reflected light 2; voltages for excess bias voltage Vₑₓ, the gate voltage of first transistor 15, SPAD 1 output, and SPAD 2 output; and a resistance value for the channel resistance of first transistor 15. The horizontal axis indicates time. Each of SPAD 1 and SPAD 2 is one of SPADs 10 in a photodetector array, and the respective locations are non-limiting. The light emitter is a diffuse light source, and there are at least two measurement targets including a relatively near measurement target and a relatively distant measurement target. Reflected light 1 is light with which a relatively near measurement target is irradiated and is incident on SPAD 1 after reflection. Reflected light 2 is light with which a relatively near measurement target is irradiated and is incident on SPAD 2 after reflection. As can be seen from FIG. 20, excess bias voltage Vex is increased over time. When an object is irradiated with diffuse light and reflected diffuse light is received from the object, since light intensity decreases in inverse proportion to the square of the distance between the light source and the object, the light intensity of reflected light from a relatively near measurement target is high and the light intensity of reflected light from a relatively distant measurement target is low. Accordingly, when detecting reflected light from a relatively near measurement target, it is possible to reduce the probability of false positive due to dark current while preventing double counting, by reducing excess bias voltage Vₑₓ and photon detection efficiency (PDE). When detecting reflected light from a relatively distant measurement target, it is possible to reduce the risk of false negatives by increasing excess bias voltage Vₑₓ and PDE. In order to achieve quenching while minimizing a dead time, resistance values may be decreased over time. In the circuit in FIG. 12, for example, it is recommended to decrease the gate voltage over time since the quenching resistor is a p-type transistor.

Distance measurement system 500 according to Embodiment 3 includes light receiver 520 including photodetector 1 described above, light emitter 510 that emits light toward a measurement target, and controller 530 that controls light receiver 520 and light emitter 510. Controller 530 receives, from light receiver 510, a signal corresponding to reflected light reflected by the measurement target, and calculates the distance to the measurement target.

After light is emitted by light emitter 510, an excess bias voltage may be increased over time and the channel resistance of first transistor 15 may be decreased over time.

Although the photodetector, photodetector array, and distance measurement system according to one or more aspects of the present disclosure have been described based on embodiments, the present disclosure is not limited to these embodiments. Embodiments achieved by applying various modifications conceived by a person skilled in the art to the embodiments as well as embodiments achieved by discretionarily combining elements from different embodiments may be also included in the range of the one or more aspects of the present disclosure, so long as they do not depart from the spirit of the present disclosure.

### Industrial Applicability

The present disclosure can be used for photodetectors, photodetector arrays, and distance measurement systems, and can be used in, for example, solid-state imaging devices, ranging devices, cameras, etc.

1. A photodetector comprising:
a single-photon avalanche diode (SPAD); and
a first resistor connected in series to the SPAD, wherein
in a recharge period in which an electric charge is discharged from the SPAD via the first resistor, an electric charge disappears from a multiplication region in the SPAD.

2. The photodetector according to claim 1, wherein
a maximum value of voltage amplification at an end, of ends of the SPAD, which is connected to the first resistor is greater than an excess bias voltage, the excess bias voltage being a difference between a voltage applied to both of the ends of the SPAD and a breakdown voltage of the SPAD.

3. A photodetector comprising:
a single-photon avalanche diode (SPAD);
a capacitor connected in parallel to the SPAD;
a first resistor connected in series to the SPAD; and
a reader that reads a voltage at an end, of ends of the SPAD, which is connected to the first resistor.

4. The photodetector according to claim 1, wherein
an excess bias voltage applied to the SPAD is less than a breakdown voltage of the SPAD, and
a resistance value R of the first resistor satisfies the following expression:
$$R > \frac{2 {E}_{BD}^{2} ln ( \frac{{CV}_{ex}^{2} W ( a α ( {E}_{BD} ) + b β ( {E}_{BD} ) )}{{qE}_{BD}^{2}} )}{( a α ( {E}_{BD} ) + b β ( {E}_{BD} ) ) {v}_{s , e} C {V}_{e x} ln ( 2 )} \qquad [ Math . 1 ]$$
where:
E_{BD} denotes an electric field strength in the SPAD;
C denotes a capacitance including a parasitic capacitance of the SPAD;
Vₑₓ denotes the excess bias voltage that is a difference between a reverse bias voltage applied to the SPAD and the breakdown voltage of the SPAD;
W denotes a depletion layer width of the SPAD;
α(E_{BD}) denotes an electron impact ionization rate under the electric field strength E_{BD};
β(E_{BD}) denotes a hole impact ionization rate under the electric field strength E_{BD};
a denotes a coefficient of the electron impact ionization rate;
b denotes a coefficient of the hole impact ionization rate;
q denotes an elementary charge; and
V_{s,e} denotes an electron saturation velocity.

5. The photodetector according to claim 2, further comprising:
a reference controller, wherein
the reference controller refers to at least one of the following five parameters and controls at least one parameter other than the at least one of the following five parameters referred to:
(i) a resistance value R of the first resistor;
(ii) a capacitance C including a parasitic capacitance of the SPAD;
(iii) the excess bias voltage Vₑₓ that is the difference between the voltage applied to the both of the ends of the SPAD and the breakdown voltage of the SPAD;
(iv) a depletion layer width W of the SPAD; and
(v) the breakdown voltage of the SPAD.

6. The photodetector according to claim 5, wherein
the first resistor is a variable resistor, and
the reference controller decreases the resistance value of the first resistor as the excess bias voltage increases.

7. The photodetector according to claim 6, wherein
the first resistor includes a first transistor, and
the resistance value of the first resistor corresponds to a channel resistance of the first transistor.

8. The photodetector according to claim 5, wherein
the capacitance C including the parasitic capacitance of the SPAD is variable, and
the reference controller decreases a capacitance value of the capacitance C as the excess bias voltage increases.

9. The photodetector according to claim 8, wherein
the first resistor includes a first transistor,
the photodetector further comprises:
a second transistor having one end at which the SPAD is connected to the first transistor; and
a second capacitor at an other end of the second transistor, the other end being opposite to the one end of the second transistor, and
the reference controller refers to the excess bias voltage of the SPAD and controls a gate voltage of the second transistor.

10. A photodetector array comprising:
N photodetectors each of which is the photodetector according to claim 1, where N is an integer of 2 or greater, wherein
N series circuits included in the N photodetectors are connected in parallel,
each of the N series circuits includes the SPAD and the first resistor that are connected in series,
N ends on a SPAD side are connected to each other, the N ends being one ends of the N series circuits,
the photodetector array further comprises a second resistor that is connected to the N ends connected to each other and is connected in series to the N photodetectors, and
a resistance value of the second resistor is less than one N-th of the resistance value of the first resistor.

11. The photodetector array according to claim 10, wherein
the N SPADs are disposed on a single semiconductor substrate, and
the N ends are connected to each other via the single semiconductor substrate.

12. The photodetector array according to claim 11, wherein
a voltage is applied, via an electrode disposed in contact with a second principal surface, to the N ends connected to each other, the second principal surface being a principal surface of the semiconductor substrate and facing the N ends connected to each other.

13. The photodetector array according to claim 11, further comprising:
a light reception area in which the N photodetectors are disposed;
a contact region disposed outside the light reception area; and
a second wire disposed in contact with a first principal surface that is a principal surface of the semiconductor substrate on a side opposite to a second principal surface, the second principal surface being a principal surface of the semiconductor substrate and facing the N ends connected to each other, wherein
a voltage is applied, via the second wire, to the N ends connected to each other.

14. The photodetector array according to claim 13, further comprising:
a peripheral circuit portion that performs control or signal processing on the N photodetectors, wherein the contact region is disposed between the light reception area and the peripheral circuit portion.

15. The photodetector array according to claim 10, wherein
the first resistor includes a first transistor,
each of the N photodetectors includes at least two transistors including the first transistor,
the first resistor is a channel resistance of the first transistor, and
the first transistor has a gate area greater than a gate area of an other transistor included in the photodetector.

16. A photodetector array comprising:
M photodetectors each of which is the photodetector according to claim 1, where M is an integer of 2 or greater, wherein
the M photodetectors are connected to each other at one end of the SPAD,
a third resistor and a third capacitor are connected at the one end of the SPAD,
the first resistor includes a first transistor,
the first resistor is the first transistor, and
a resistance value r′ of the third resistor satisfies the following expression:
$${r}^{′} > \frac{2 {E}_{BD}^{2} ln ( \frac{C {V}_{e x}^{2} W ( a α ( {E}_{BD} ) + b β ( {E}_{BD} ) )}{q {E}_{BD}^{2}} )}{N ( aα ( {E}_{BD} ) + b β ( {E}_{BD} ) ) {ν}_{s , e} {CV}_{ex} ln ( 2 )} \qquad [ Math . 2 ]$$

17. The photodetector array according to claim 16, wherein
the first transistor is:
in a conducting state in a reset period for resetting the SPAD; and
in a non-conducting state in an exposure period for detecting light incident on the SPAD.

18. The photodetector array according to claim 16, wherein
the first transistor includes a channel having a conductivity type same as a conductivity type of an end of the SPAD at which the first transistor is connected.

19. The photodetector array according to claim 16, wherein
a capacitance value of the third capacitor is greater than a capacitance of the SPAD.

20. A distance measurement system comprising:
a light receiver including the photodetector according to claim 1;
a light emitter that emits light toward a measurement target; and
a controller that controls the light receiver and the light emitter, wherein
the controller receives, from the light receiver, a signal corresponding to reflected light reflected by the measurement target, and calculates a distance to the measurement target.

21. The distance measurement system according to claim 20, wherein
the first resistor includes a first transistor,
after the light emitter emits light, an excess bias voltage is increased over time, the excess bias voltage being a difference between a voltage applied to both ends of the SPAD and a breakdown voltage of the SPAD, and
a channel resistance of the first transistor is decreased over time.
